(19) United States
(12) Patent Application Publication
(10) Pub. No.: US 2016/0348271 A1
(43) Pub. Date: Dec. 1, 2016

(54) Integrated System of Silicon Casting and Float Zone Crystallization

(71) Applicants: Jagannathan RAVI, Bedford, MA (US); Alleppey V. HARIHARAN, Austin, TX (US)

(72) Inventors: Jagannathan RAVI, Bedford, MA (US); Alleppey V. HARIHARAN, Austin, TX (US)

(21) Appl. No.: 15/168,971

(22) Filed: May 31, 2016

Related U.S. Application Data
(60) Provisional application No. 62/167,945, filed on May 29, 2015.

(51) Int. Cl. C30B 13/20; H01L 31/18; C30B 29/06; C30B 15/14; C30B 13/24

(52) U.S. Cl. CPC C30B 13/20; C30B 15/14; C30B 13/24; C30B 29/06; H01L 31/1824

(57) ABSTRACT

The present invention is directed towards an integrated and economic process for making mono-crystalline silicon for photovoltaic applications. It utilizes high purity, low dopant metallurgically produced silicon, in particular, silicon recovered from silicon manufacturing processes, such as kerf silicon processed through a metallurgical furnace process. Liquid silicon from the metallurgical process is cast into specific forms and utilized for float zone purification and crystallization to make mono-crystalline silicon ingots and wafers for photovoltaic cell fabrication.

### INCORPORATION BY REFERENCE

All patents, patent applications and publications cited herein are hereby incorporated by reference in their entirety in order to more fully describe the state of the art as known to those skilled therein as of the date of the invention described herein.

This application claims the benefit of priority under 35 U.S.C. §119(e) to co-pending U.S. Patent Application No. 62/167,945 filed on May 29, 2015, entitled “FLOATING ZONE METHOD IMPROVEMENTS,” which is incorporated herein by reference in its entirety.

### FIELD OF INVENTION

The present invention is directed towards an integrated method to process a silicon feedstock material, in particular kerf-derived metallurgical silicon, through float zone purification and crystallization and form mono-crystalline silicon ingots. It is primarily applicable to production of crystalline silicon wafers for use in photovoltaic systems.

The present invention is also directed towards production of shaped polysilicon rod feedstock for subsequent float zone processing.

The present invention is also intended for direct use of short wavelength lasers as heat source for the float zone process.

The present invention is also directed towards adaptation of the float zone method to produce kerf-less silicon wafers.

### BACKGROUND OF THE INVENTION

Crystalline silicon solar cells are the dominant photovoltaic (PV) technology today. They use multi-crystalline or mono-crystalline silicon wafers. The solar cells made from mono-crystalline silicon wafers have a higher efficiency, and are being increasingly used by several manufacturers to reduce overall cost of PV systems.

The mono-crystalline silicon wafers most often are fabricated from a single crystal silicon boule pulled from a molten pool of very high purity silicon using the Czochralski (CZ) method. This method utilizes a container crucible for the melt pool, and initially uses a seed crystal to begin the crystal growth into the desired crystal size. The boule can be only cylindrical in shape. The CZ method is well tested and reliable, but it is inefficient in the utilization of silicon, electricity, other consumables, has long batch times, and hence expensive to operate.

A second process that can produce high quality silicon single crystal for photovoltaics is the Float Zone (FZ) Method (Ref: Float zone (FZ) silicon: A potential material for advanced commercial solar cells, H.-J. Rost et. al. Cryst. Res. Technol. 47, 273-278 (2012); Float-zone silicon for high volume production of solar cells, J. Vedde et. al., 3rd World Conf. on Photovoltaic Energy Conversion, Osaka, Japan 2003). In this method, which is an adaptation of zone refining, a section of the free-standing (crucible-less) polysilicon feedstock rod is melted by use of radio frequency induction coil and allowed to crystallize. The crystallization zone and the melt zone are then swept typically from one end of the rod to the other end by moving the induction coil. Each such pass provides for improvements in the purity of the resulting crystal. The FZ method, however, is even more expensive than the CZ method (Ref: FZ and CZ crystal growth: Cost driving factors and new perspectives, W. von Ammon, Physical Status Solidi, No. 11, 2461-2470 (2014)) because of the stringent requirement for the polysilicon feed rods for the FZ process, such as
(a) Low dopant levels—since the dopants boron and phosphorus in silicon have high segregation coefficients (0.8 and 0.35, respectively), they cannot be effectively removed by the CZ or FZ methods.
(b) Right shape—typically rods with circular cross-section, since such silicon rods are what are available for use as feedstock, and which are the Siemens-processed rods or CZ-grown rods.
(c) No cracks or physical defects—the FZ method is used to form single crystals by localized high temperature scanning; if the feed rods have internal defects, they form regions of dislocations preventing single crystal formation. If they have external physical defects, such as surface cracks or surface roughness as with higher speed deposition Siemens process rods for photovoltaic application, they cause to initiate arcing from the induction coil.
(d) No inclusions, such as SiC, Si₃N₄ or SiO₂—since these will all affect the single crystal formation by the FZ method.

The requirement of low dopants (esp. boron and phosphorus) in silicon is particularly restrictive, as well as expensive, as this necessitates high purity polysilicon deposited by the Siemens process. The polysilicon rods from the Siemens process can be used, with care, as feedstock for the FZ process, but have the following set of impediments that restrict usage while adding cost:
1. Rods from the Trichlorosilane (TCS)-based CVD process require high deposition temperature (˜1100 C) limiting, in practice, the maximum diameter of the silicon rod to about 150 mm.
2. In order to grow defect-free rods, the silicon deposition rate needs to be lowered, thus increasing the process time.
3. Silane (SiH₄)-based CVD process requires a lower deposition temperature (˜800 C) allowing for larger silicon rod diameters, but it is more expensive than the TCS-based process.

Alternately, polysilicon chunks made from the silicon rods of the TCS- or silane-based Siemens process and without regard to defects can be melted and drawn by the CZ process to provide FZ suitable silicon rod. However, the additional CZ process step, prior to FZ processing, adds considerable cost.

Polysilicon granules produced by the Fluid Bed process have been suggested as direct feedstock for the FZ process method (Ref: FZ and CZ crystal growth: Cost driving factors and new perspectives, W. von Ammon, Physica Status Solidi, No. 11, 2461-2470 (2014)), but this method has not made progress due to great technical difficulties and added cost.

Currently, while it is well known that crystalline silicon ingots produced through the FZ crystallization process is superior in quality for PV wafer use compared to that from CZ process, adaptation and use of the FZ crystallization process is difficult and impractical for (a) lack of cost effective polysilicon feedstock, and also (b) casting technology, as an alternative to expensive Siemens or CZ grown rods, to produce silicon rods.

Hence, for photovoltaic applications, the use of single crystal silicon wafers made through the FZ method is generally restricted to providing test wafers for laboratory process design and testing, and where application cost and production methods are unimportant.

A potential source for low cost polysilicon is to recover the high purity silicon from kerf silicon waste. However, the PV industry does not have a robust and industrial process to recover such high purity silicon from kerf silicon waste (Ref: Waste Not, Want Not, A Case for Recycling Silicon Waste Powder Kerf, Keith G. Barraclough, KGB Consulting Ltd, 2006, Beneficial and Technological Analysis for the Recycling of Solar Grade Silicon Wastes, Anping Dong, Lifeng Zhang, and Lucas N. W. Damoah, JOM, Vol. 63 (1), 2011) except for the specific processes outlined by the authors in the US Patent Application 2013/0319391, “Recovery of Silicon Value from Kerf Silicon Waste” and U.S. Pat. No. 9,061,439, “Recovery of Silicon from Kerf Silicon Waste”.

A potential cost-effective method to produce defect-free silicon feed rods for the FZ process is to directly utilize the high purity liquid silicon from the metallurgical process furnace by processes described in this patent application.

Directly casting the liquid silicon from carbothermic metallurgical furnaces into solid forms is not developed and practiced in the silicon manufacturing industry. Typically the molten silicon output of the furnaces are tapped out and allowed to cool before crushing them into chunks. The high level of metallic, dopant and non-metallic impurities in the widely available MG-Si also does not permit direct use of such silicon for photovoltaic or semiconductor applications.

The integrated process of kerf-derived metallurgical silicon, direct silicon form casting and utilization of FZ crystallization process for the formed cast silicon as described in this patent application will provide practical ways to drastically reduce the cost of mono-crystalline silicon and silicon wafers for PV use.

### SUMMARY OF THE INVENTION

Methods are disclosed to recover silicon from the kerf silicon material waste from a silicon wafer manufacturing process, cast the silicon product into a form suitable for float zone crystallization process and produce high purity single crystalline silicon ingot at competitive costs.

Methods are disclosed to provide robust, industrially practical and cost-effective methodology to recover silicon value from kerf silicon and convert the recovered silicon into high purity crystalline silicon.

The process uses a metallurgical carbothermic reduction of the processed kerf silicon waste material. A physico-chemical head-end process treatment of the kerf silicon waste material is performed prior to the metallurgical conversion to remove and reduce the extraneous impurities in the silicon waste material. High purity crystalline silicon can be realized from the recovered high quality silicon very effectively through a final float zone crystallization process.

In one or more embodiments, the silicon material from metallurgical processes is utilized in one of several silicon form casting processes.

In any of the above noted embodiments the silicon form casting processes comprises mold casting, continuous casting and electromagnetic cold crucible casting.

In any of the above noted embodiments the silicon form casting processes comprises forms with uniform cross sections and which are cylindrical, square, rectangular or other defined cross sections, and variable lengths.

In any of the above noted embodiments, the kerf silicon waste material comprises intrinsically pure >99.999% high purity silicon.

The methods described herein utilize recoverable sources of silicon such as from kerf silicon waste and effect to produce high quality float zone processed crystalline silicon ingot through an overall process scheme that is cost- and process-effective for the photovoltaic industry for manufacturing high quality silicon wafers, and is expected to have a major impact on this industry whose growth demand and growth potential are strictly dependent on continued cost reductions and ease of manufacture.

Methods are herein described for the float zone crystallization process that while typically utilizes electromagnetic induction heating of the crystal forming zone can be improved by use of short wavelength laser heating.

Method is herein described for modifying the float zone crystallization process to make kerf-less silicon wafers from a specific silicon feedstock form.

### Definitions

As used herein, the wire saw process to produce silicon wafers from silicon ingot includes loose abrasive silicon carbide slurry on bare wire based process and/or fixed abrasive diamond on wire based process.

As used herein ‘kerf silicon’ refers to the silicon material produced during the cutting or grinding process, such as ingot shaping, wire saw slicing of silicon ingots to form silicon wafers, grinding and polishing of silicon wafers and silicon parts. It is typically contaminated with the abrasives and metals utilized to saw the ingot, the carrier fluid or other chemicals in the slicing, grinding and polishing medium, and other process elements.

As used herein ‘kerf silicon waste’ refers to the dry powder or cake of kerf silicon as it is typically processed in preparation for disposal by the silicon fabrication industry. Carrier or polishing fluids are recovered from the kerf silicon; kerf silicon may also be treated to remove the bulk of the silicon carbide or diamond. However, residual carrier fluid and significant amounts of silicon carbide or diamond remain in the kerf silicon waste, as well as metallic and non-metallic impurities.

As used herein, “ dopants ” refers to the dopant elements found in semiconducting silicon materials, which typically include III-V dopant elements such as the p-type group III acceptor elements B, Al, Ga and In and n-type group V donor elements In, P, As and Sb.

As used herein, “silicon granules and chunks” refer to the high purity silicon granules realized in the silicon granule manufacturing process in fluid bed reactors, and that resulting from crushing silicon rods from the Siemens process to produce smaller silicon chunks.

### BRIEF DESCRIPTION OF THE DRAWINGS

This invention is described with reference to the following drawings that are presented for the purpose of illustration only and are not intended to be limiting of the invention.

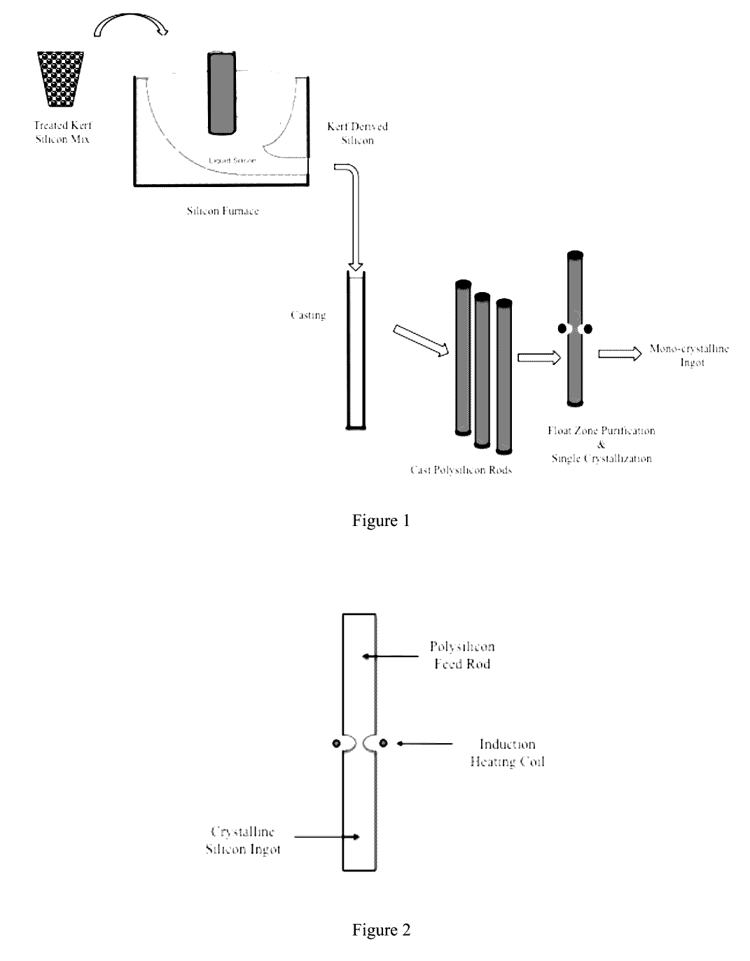

The reference process flow for conversion of kerf silicon waste through carbothermic reduction, silicon rod forming and FZ process is described in FIGS. 1.

A generalized process scheme according to one or more embodiments of the present invention for the FZ crystallization process to make crystalline silicon is shown in FIG. 2.

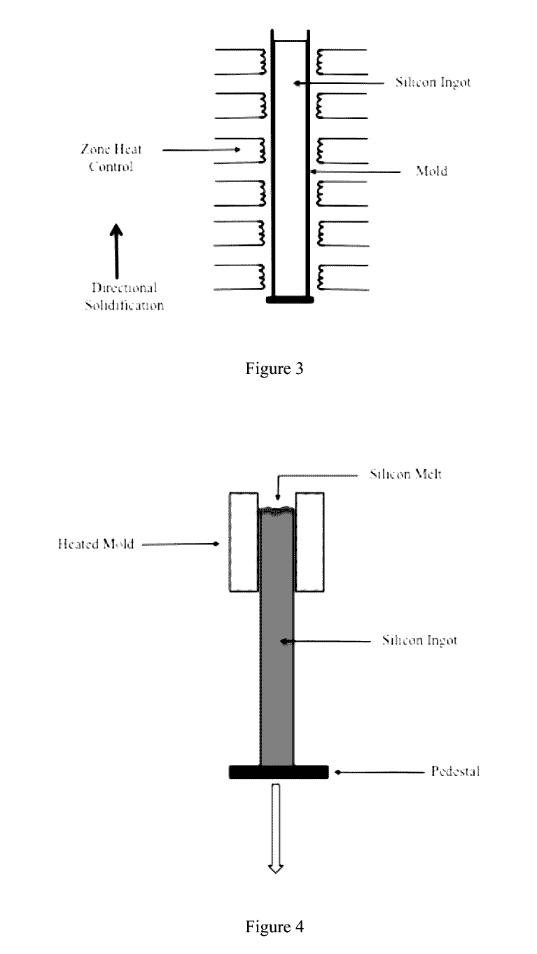

A generalized process scheme according to one or more embodiments of the present invention to cast silicon ingot in a mold is shown in FIG. 3.

A generalized process scheme according to one or more embodiments of the present invention to realize continuous cast silicon rod shape is shown in FIG. 4.

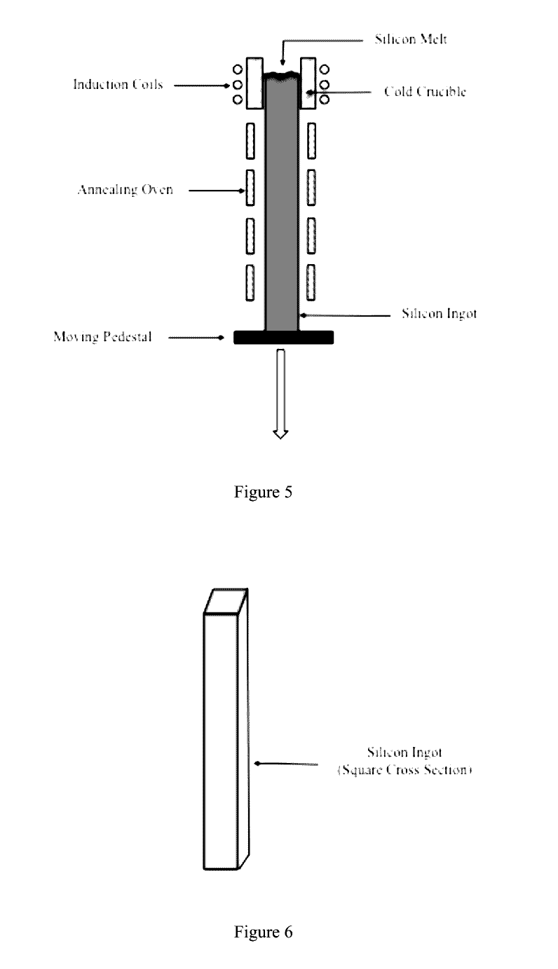

A generalized process scheme according to one or more embodiments of the present invention to cast silicon ingot in an electromagnetic cold crucible (EMCC) process is shown in FIG. 5.

A generalized process scheme according to one or more embodiments of the present invention to cast silicon shape in a square configuration is shown in FIG. 6.

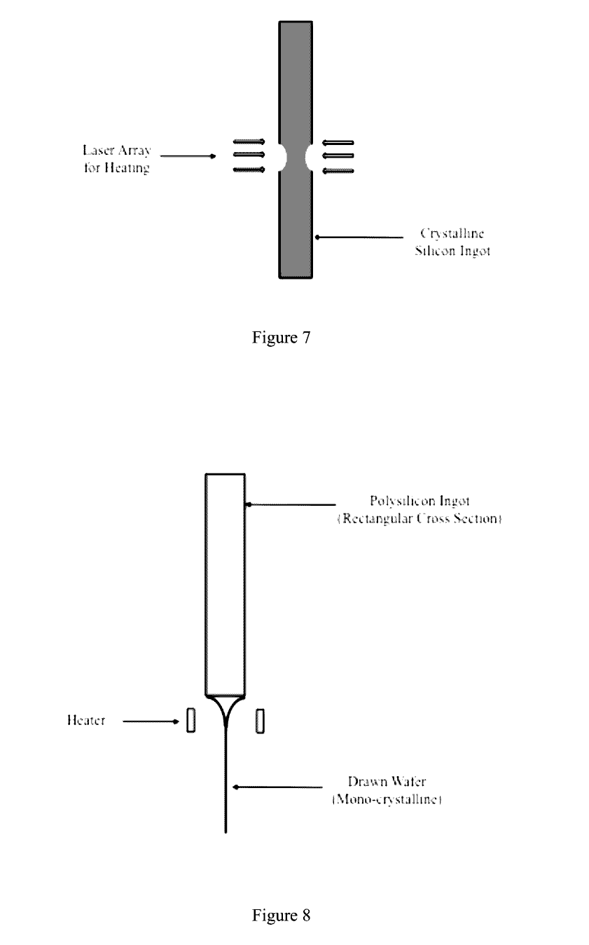

A generalized process scheme according to one or more embodiments of the present invention to use short wavelength laser as heat source for the FZ process is shown in FIG. 7.

A generalized process scheme according to one or more embodiments of the present invention to make kerf-less silicon wafers by an adapted FZ process is shown in FIG. 8.

### DETAILED DESCRIPTION OF THE PREFERRED EMBODIMENTS

### Kerf-Derived Metallurgical Silicon+Float Zone Processing

A method of converting kerf silicon waste into polysilicon, then casting the liquid polysilicon into cylindrical rod shape and submitting such rods to float zone process of manufacturing crystalline silicon ingot is described with reference to FIG. 1. FIG. 2 depicts, in outline form, FZ crystal growth process.

The method includes providing an intrinsically high purity silicon material mixed with abrasives and other extrinsic metallic impurities from a silicon wafer manufacturing process, removing such extrinsic impurities, recovering the silicon material in a carbothermic metallurgical process, casting a silicon shape from the silicon melt, and utilizing the cast silicon shape in a float zone purification and crystallization process to make PV-grade mono-crystalline silicon ingot.

The method initially utilizes the process outlined in Patent Application 2013/0319391 (Ref: “Recovery of Silicon Value from Kerf Silicon Waste”). In one embodiment, wire saw kerf, consisting of silicon, SiC or diamond abrasives, metallic impurities and slurry carrier fluid is first treated to reduce and remove carrier fluid, metallic and other impurities. Subsequently the intrinsically high purity silicon and silicon values from the kerf mix (i.e. with low dopants content) is recovered in an arc furnace process involving carbothermic reduction. A subsequent directional solidification process (DSS) was suggested in the patent application referenced above as a way for further reducing the metallic impurities in the recovered silicon, which then is suitable for multi-crystalline silicon wafers for use in solar cells. However, single crystal ingots or wafers were not suggested with the steps outlined in the earlier patent application.

The key and novel variation proposed here is that the liquid silicon from the arc furnace is cast into long cylindrical rods that are directly suitable as feedstock for a subsequent FZ process. Casting of metal cylinders is well established in metallurgical industries and to some extent for silicon blocks also. These are to be adapted appropriately for silicon to make defect-free long rods. The cast rods from kerf silicon source (for p-type) will typically have metallic impurities of <500 ppm, dopants boron <0.5 ppm, and negligible phosphorus. The boron level is the amount maintained in the original silicon ingot before wafering, and hence it is the right level for making new silicon ingots and wafers. Minor adjustments to this level are still possible during the FZ process. If the kerf silicon is sourced from n-type ingot sawing, the dopant level in the kerf-derived metallurgical silicon feedstock material will similarly be suitable for n-type silicon wafers. Thus, the kerf-derived metallurgical silicon feedstock (in the form described) counter intuitively becomes low cost silicon feedstock for the FZ process in place of Siemens- or CZ-derived silicon rods. The entire process avoids the need for expensive gaseous purification schemes, Siemens deposition process and/or the subsequent crystal growing by the CZ method.

Standard metallurgical grade silicon (MG-Si) is also a product from an arc furnace process of carbothermic reduction of silica. It may also be cast into cylinder-shaped rods. However, its purity is very low, 98-99%, and contains significant levels of metallic impurities and dopants, boron (40-60 ppm) and phosphorus (20-50 ppm). Such MG-Si is used as a feedstock for further chemical purification in the Siemens or FBR polysilicon manufacturing processes. Standard MG-Si, thus, is not suitable as an FZ feedstock, especially since the dopant levels cannot be reduced to the required extent, even by the additional refining during the FZ process.

A material of higher purity level than the MG-Si is the upgraded metallurgical silicon (UMG-Si). Even with additional metallurgical purification the dopant content of the UMG-Si is ˜5 ppm boron and ˜5 ppm phosphorus. Thus, for a p-type silicon ingot, the B dopant level is at least 10 times the level from the kerf-derived metallurgical silicon. The FZ method by itself cannot reduce this high level of dopants from the UMG-derived silicon rod to levels needed for solar wafers.

The levels of metallic impurities in the kerf-derived metallurgical silicon feedstock are significantly reduced in the FZ process, because of their low segregation coefficients, and by use of one or at most two FZ crystallization passes. The dopant levels will not need to be reduced. The resulting single crystal rod output can be sawn into silicon wafers for solar cell processing.

The cost of kerf-derived metallurgical silicon is expected to be only about a fifth compared to currently used FZ suitable polysilicon feedstock. The cost of the mono-crystalline wafer will be reduced by nearly half, from a combination of reduction in feedstock and other consumables cost and higher throughput compared to CZ method of single crystal ingot production.

Within the purview of this patent, other metallurgically processed high purity, low dopant silicon can be used to cast liquid silicon into FZ suitable feedstock. These include, for example, silicon from carbothermic reduction of high purity silica (Ref: U.S. Pat. No. 8,568,683) and metallurgical grade silicon purified by liquid metal refining (Ref: U.S. Pat. Nos. 7,727,503, 7,955,433) or slag refining (Ref: U.S. Pat. No. 7,931,883).

Within the purview of this patent, the metallurgical process for producing high purity, low dopant silicon may make use of internal or external heating means such as submerged arc, electromagnetic induction, microwave and resistance.

In another embodiment, an adaptation of the integrated kerf-derived metallurgical silicon-to-silicon shape casting to FZ crystal growth process is the direct use of high purity polysilicon chunks from the Siemens manufacturing process (or polysilicon granules from the FBR manufacturing processes) in an integrated polysilicon-to-silicon shape casting-to-FZ process. Such an adaptation, especially with use of electromagnetic cold crucible casting of polysilicon rods of defined cross sectional shapes (circular, square, rectangle, etc. described in the following sections), is an implementable technology in the PV manufacturing schemes.

### Silicon Shape Casting

While metal shape casting is well known in the metallurgical industries to cast metals with casting shrinkage (i.e. typically solid has a higher density than the liquid at the freezing point), silicon introduces significant problems because of its expansion (˜7.5%) during the solidification process (i.e., solid has a lower density than the liquid at the freezing point (Ref: Calculation of density and heat capacity of silicon by molecular dynamics simulation, R. Kojima Endo and Y. Fujihara, M. Susa, High Temperatures—High Pressures 35/36(5) 505-511 (2003)).

| | |
|---|---|
| Freezing point, silicon | 1685K |
| Density (ρ) in gcm⁻³: | |
| Crystalline silicon | ρ = 2.33 − 2.19 × 10⁻⁵ T (100 − 1685K) |
| Liquid silicon | ρ = 2.54 − 2.19 × 10⁻⁵ T − 1.21 × 10⁻⁸ T² |
| | (1685 − 3000K) |

Thus, for silicon at the freezing point of 1685 K (1412 C)

| | |
|---|---|
| ρ _{solid} = 2.293 gcm⁻³, | Specific Volume 0.436 cm³/g |
| ρ _{liquid} = 2.468 gcm⁻³, | Specific Volume 0.405 cm³/g |

Once solid silicon of a defined shape is formed from the liquid at the freezing point, the solid shape, as it cools to the room temperature, only shrinks in volume.

In the PV industry, silicon casting to manufacture large size multi-crystalline silicon ingot block is a well established process encompassing the heat exchanger method or the directional solidification method (Ref: Casting Technologies for Solar Silicon Wafers: Block Casting and Ribbon-Growth-on Substrate, A. Schönecker, L. J. Geerligs and A. Müller, European Commission project, ENK6-CT2001-00574 (2002); High Throughput—High Yield Solar Silicon Ingot Production, A. Muller, 1st International Advanced Photovoltaic, Manufacturing Technology Conference, Munich, 13th Apr. 2005). The cast ingot block weight has increased over the years from 250 kg to 800 kg per crucible batch. The height of the solidified ingot block is typically no more than 0.4 meters. However, for efficient use as FZ process feed rods, the cast silicon rods and blocks need be of length 2-3 meters and whose diameter or side width are to be 150-200 mm. Processes for producing long defect-free rods, blocks and other shapes of silicon are as yet unknown in the industry.

### Silicon Casting Methodologies

With high purity, low dopant metallurgical silicon (such as kerf-derived or other metallurgical processed silicon indicated earlier) as the feed material, five silicon casting processes are defined here, comprising three mold casting processes, one continuous casting process and one electromagnetic cold crucible casting process. For manufacture of cast silicon rods a solidification rate of 20 cm/hour to 80 cm/hour and even as high as 120 cm/hour may be required to be process- and cost-effective. While such a high rate may be detrimental for multi-crystalline silicon growth (typically only 1-2 cm/hour is practiced), crystal growth is not the goal in the silicon casting. Realizing silicon ingots that are defect-free and inclusion-free are the primary purposes. Such high-speed process for silicon casting has not been reported in the industry.

### Mold Casting

The three mold casting processes are:
1. Liquid silicon from the arc furnace is directly used without or with a tundish to feed the casting molds.
2. The liquid silicon from the arc furnace is transferred to a batch feed crucible for liquid silicon to feed the casting molds.
3. Liquid silicon from the arc furnace is solidified, then appropriate amounts of the silicon are broken up to small pieces, then remelted in a crucible from which the liquid is fed to the casting molds. The remelt crucible can be a batch feed crucible, or dedicated crucible on top of the casting mold(s).

Casting defect-free large, significant size and long cylindrical rods, square rods, rectangular rods, other shapes etc., of polysilicon requires a very controlled solidification process to prevent mold container breakage, and to provide crack-free and inclusion-free silicon ingots. When casting molds are used, the mold is heated and held at a temperature above the melting point of silicon (1412 C) prior to pouring liquid silicon into the mold. When such molds are used for the required silicon ingot shapes the process will be adapted for very controlled cooling of the liquid—solid interface of the type in directional solidification to ensure defect-free solidification in the mold. To that extent, the mold system will incorporate multiple heaters and heat control systems along the full length of the mold system to aid in the controlled solidification process. Molds are of the type made of high purity fused quartz or high purity impervious graphite and pyrolytic carbon, appropriately coated, typically with silicon nitride. Other coating materials are boron nitride or silicon carbide/nitride (silicon carbonitride), all of which have low wetting by liquid silicon. In addition, the silicon casting needs to be performed in an inert gas environment to prevent oxidation and nitridation of the silicon which will cause solid inclusions in the cast shape.

A schematic representation of mold -based equipment system to cast silicon is depicted in FIG. 3.

If the silicon rod casting is done incorporating a level of directional solidification, the resulting cast shape will have an order of magnitude purification of the kerf-derived metallurgical silicon from metallic impurities, with effective segregation coefficients for the impurities close to the equilibrium segregation coefficients over 90% of the cast length.

### Continuous Casting

Another method of obtaining silicon rods is by continuous casting. Molten silicon is fed into a mold from a crucible or tundish. The silicon casting is formed in the mold but moves quickly through it. An inert pedestal to enable solid silicon to form and rest at the bottom of the mold and moving relative to the mold would aid in this process. The casting coming out in the opposite end of the mold has the cross sectional shape of the mold but its length is much longer and depends on the amount of molten silicon being supplied. Two options are possible—fixed length cast rod or continuous cast rod cut into fixed lengths below the mold. In the latter case, the casting process is not stopped after each rod length is formed but continues in an indeterminate manner as long as the liquid silicon level is maintained in the tundish and casting conditions remain optimal and unchanged.

Good control of the entire process is essential for the casting conditions like the pour rate, mold wettability, casting withdrawal, inert atmosphere, etc. so that a defect-free cast rod is obtained. The mold is typically heated and the casting is cooled from the outside in. The peculiar property of silicon mentioned earlier—lower density on solidification—might be used advantageously here. The still molten central core, being squeezed as the solidification approaches the center, can expand into the liquid metal above and within the mold and thus the casting formed can be free of pores, cracks and other defects.

The provision of a minimal supplemental electromagnetic force to just keep the solidifying silicon from direct contact with the mold material will improve the process of continuous casting of silicon.

A conceptual method for continuous casting of silicon ingot from liquid silicon feed is depicted in FIG. 4. Such a continuous casting method for defect-free silicon described above and encompassing the entire process and equipment is not available in the industry.

### Electromagnetic Cold Crucible (EMCC) Casting

In another embodiment, an alternate process to manufacture silicon rods for the FZ process is to adapt the electromagnetic cold crucible casting process (Ref: Electromagnetic Casting Apparatus for Silicon, Kyojiro Kaneko, US Patent Appln. 2012/0230902 (2012)). The EMCC is a continuous casting process and which will facilitate to produce long silicon rods for FZ use. While this process typically utilizes solid feed of silicon, the process will require to be developed and improved to feed controlled amount of liquid silicon and couple with rigorous solidification process control to realize large defined size and defect-free polysilicon casting shapes for use as feed rods and blocks for the FZ process. Such processes to produce defect-free long rods and blocks of silicon in practical production time frame are as yet unknown in the industry. FIG. 5 depicts equipment for EMCC casting of silicon ingot from liquid silicon feed.

The silicon single crystal rod output from the FZ process can be sawn into silicon wafers for solar cell processing.

### Variations of the Embodiments

Adaptation of the process of this invention for alternate silicon feedstock shapes for the FZ crystallization process to directly obtain silicon wafers, and potential use of laser heating in the FZ crystallization process are described in the following sections.

### Shaped Polysilicon Rod Feedstock for Float Zone

The FZ method, as hitherto practiced, typically produces circular cross-section silicon single crystal. These have to be trimmed to a square or pseudo square shape prior to wafering for use in solar cells, thus wasting expensively produced high purity silicon. There are attempts in the industry to produce nearly square cross-section single crystal rods by means of square heating elements in the FZ equipment. But since the only possible existing useable feedstock is a circular rod (as explained earlier), the square shape sought needs a conversion from the circular cross section to a square cross-section during the melt phase and subsequent solidification during the FZ processing. The molten silicon from the circular rod is, hence, coerced to a squarish shape by the heater. Unlike with standard FZ processing there is no rotation of the feedstock or heater. To get very square wafer shape, a further trimming will still be required.

The casting methods for kerf-derived metallurgical silicon described in earlier section can enable casting a square shaped silicon rod for the FZ feed in a direct way. In addition to casting cylindrical, circular cross-section polysilicon feed rods, the casting shape can be made to yield square or rectangular cross section rods. Such methodology is obviously impossible for silicon rods made using the Siemens process or pulled by the CZ method, in either of which only cylindrical rods with circular cross sections are possible. With the square or rectangular cross-section rods the FZ process heater fits around the perimeter of the rod equidistantly. There is also no rotation of the silicon rod relative to the heater. Thus the re-solidification of the molten silicon into the single crystal can remain square or rectangular in cross-section.

FIG. 6 is depicts a long, square configuration silicon rod geometry.

### Variation of EMCC Casting

In a variation of integrated kerf silicon to FZ purification and single crystallization, the EMCC method can be used in two stages—an upstream station where the mix of kerf silicon, silicon oxide and silicon carbide or carbon (if from treated diamond wire saw kerf residue) is carbothermically reduced and converted to liquid silicon using electromagnetic induction or microwave heating, instead of an arc furnace, followed by electromagnetic cold crucible casting in the next downstream station. This production method is expected to reduce the cost of feedstock for FZ process even further.

### Float Zone Process Modifications

In the FZ crystallization process the targeted heating in the melt region of the silicon feed rod is usually provided by contact-less electromagnetic induction coils. This arrangement allows the relative position of silicon rod and heater to be moved up and down. The cylindrical polysilicon rod is traditionally either from the Siemens or CZ process. When cast rod feedstock is used, it is possible that large grains present in the material may cause arcing to the heating coil. This problem may be reduced or avoided by operating at a lower frequency, for example 1.5-2 MHz, instead of the usual 2-3 MHz.

A higher level of heat control is possible by using an array of laser beams that are well absorbed by the silicon. Specifically diode or fiber lasers that emit in the visible to near IR wavelengths, more commonly in the 700-1200 nm wavelength range, are particularly suitable for the application (Ref: U.S. Pat. No. 9,067,792, “Laser conversion of high purity silicon powder to densified granular forms” and U.S. Pat. No. 9,206,508, “Laser assisted Chemical Vapor Deposition of silicon”). The laser beams can be narrowly coupled to the silicon in the heat zone. There would be no possibility of arcing as typically may occur with electromagnetic induction coils and which disrupt the crystal growth process. The energy from the laser array can be also more precisely controlled both spatially and temporally as required for uniform crystal growth compared to the electromagnetic induction heaters.

FIG. 7 shows laser heating for a cylindrical rod. It should be obvious that the laser heating can be applied to any shape rod described above for single crystallization and kerf-less wafer drawing by the FZ method (as described in the next section).

The laser heating can be used either by itself or in conjunction with the electromagnetic induction coils for the heat energy input and heat control of the FZ crystallization process

### Kerf-Less Wafers Using Float Zone Method

Single crystal silicon ingots or boules have to be sawn into wafers that are then made into solar cells or for electronic or other applications. This process adds complexity, cost and significant amount of silicon wastage (kerf loss). Ideally, the wafer can be made in a ‘kerf-less’ way, i.e. without having to saw from an ingot. This is not possible at all with the CZ method as the process of crystal growth involves rotation of the growing boule creating a solid volume from which wafers would need to be sawn.

There are many methods described for kerf-less wafer making. Examples are
1. casting from a molten silicon bath (only multi-crystalline wafer is possible, since the crystallization occurs simultaneously over large areas rather than grow outwards from a single seed crystal)
2. drawing a sheet from a molten silicon bath using a seed crystal (experimental process—technically very complex)
3. peeling a thin wafer from a single crystal block of silicon (various cleaving methods are reported, but none shown on a large scale)
4. growing a wafer thin silicon film on a substrate for subsequent peeling (laboratory results only reported)
5. horizontal and vertical ribbon growth (not demonstrated for single crystal structure)

In the standard FZ method using a circular cross-section cylindrical rod silicon feedstock, pulling or drawing thin silicon wafers, mono- or multi-crystalline, is also not possible due to a combination of feed rod geometry, heater geometry, rod rotation, etc.

However, it is possible to adapt the FZ method to draw a silicon single crystal sheet wafer with appropriate feedstock shape and heater geometry to provide for uniform heat at the melt zone, so that rotation is not necessary to achieve the desired thermal profile. The silicon feedstock rod cross-section will need to be a rectangular shape of high aspect ratio, i.e., with relatively long side length and a narrow side width (in contrast, a square cross section would have an aspect ratio of 1). The heater shape and power, are to be such that at one end of the rod the silicon is heated and is squeezed forming a neck that can then be pulled into a thin long wafer by attaching a starting seed crystal. The heaters could be a combination of electromagnetic induction coil and laser array.

It is to be understood that prior to drawing a continuous mono-crystalline silicon wafer, the rectangular silicon feedstock rod would have been float zone refined to high purity in one or more FZ passes, and made suitable for solar cell fabrication, just as is the case for forming a silicon ingot from which wafers will be sawn.

In order to be able to pull a wafer directly from the feedstock silicon rod, the right conditions at the silicon solid-liquid interface have to exist. With a suitable aspect ratio (ratio of side length to side width for the rectangular cross section of silicon) and applied heat distribution, the balance of adhesive forces between the liquid and solid silicon surface and the cohesive force between molecules in the liquid silicon will cause the formation of a meniscus. The liquid silicon away from the solid feedstock surface crystallizes at the top of the meniscus at the points of seed attachment. This makes it possible to continuously pull a wafer sheet of uniform thickness while maintaining the structure of the seed crystal. The minimum aspect ratio is expected to be 3, preferably between 20 and 40 and even as high as 100.

The seed attachment and necking are also very important to keep the single crystal propagation in two dimensions only. The heat energy and pull speed will be carefully controlled at this stage and to assure single crystal structure and uniform resistivity in the drawn wafer. Incorporating minimal thermal gradients and controlled heat removal in the process, the FZ method will be adapted to directly produce silicon wafers. It is to be understood that multi-crystalline wafer can also be drawn in a like manner with a change of process conditions, for example, if the pull speed were increased.

The float zone refining and wafer drawing can be combined into a single operation with appropriate engineering and process design modifications.

FIG. 8 shows the single crystal wafer being pulled downwards from the feedstock. It is also possible to pull the wafer up from the feedstock located below in a variation of the ‘pedestal method’ of FZ purification and crystallization.

The present invention provides the steps and details of an integrated and economic process to make mono-crystalline silicon ingots and wafers from kerf silicon by use of metallurgical furnace process, liquid silicon casting of shapes and float zone refining and crystallization.

While various embodiments and details are described in the specification, it is to be understood that these embodiments and details are described solely as examples of the breadth and scope of the processes of this invention and without limitation. Many variations and modifications will be apparent to those skilled in the art of silicon processes. The claims are to be interpreted accordingly to facilitate such variations and modifications.

What is claimed is:

1. An integrated system for manufacturing mono-crystalline silicon ingot for photovoltaic use comprising:
i. producing high purity liquid silicon in a metallurgical process
ii. casting the liquid silicon into a long, defect-free shaped silicon feedstock rod
iii. heating the silicon feedstock rod by contactless means and
iv. using float zone process to further refine the purity of the silicon feedstock rod and converting it into a mono-crystalline ingot.

2. The method according to claim 1 wherein the high purity liquid silicon is derived from the group of kerf silicon waste, silicon dust from silicon granule production and silicon crushing waste from making chunks out of silicon rods.

3. The method according to claim 2 wherein the kerf silicon waste contains abrasive material at least one from the group of silicon carbide and diamond.

4. The method according to claim 1 wherein the high purity liquid silicon is produced in a metallurgical furnace process in at least one from the group of internally and externally heated furnaces.

5. The method according to claim 4 wherein the metallurgical furnace is a submerged arc furnace.

6. The method according to claim 1 wherein the silicon casting process comprises at least one from the group of mold casting, continuous casting and electromagnetic casting.

7. The method according to claim 6 wherein the solidification rate of silicon casting is 20 cm/hour to 80 cm/hour and as high as 120 cm/hour.

8. The method according to claim 1 wherein the cast silicon feedstock rod cross section shape comprises at least one of circular, square and rectangular.

9. The method according to claim 1 wherein the contactless heating means comprises at least one from the group of electromagnetic induction coil and laser array.

10. The method according to claim 9 wherein the heating means comprises a combination of both electromagnetic induction coil and laser array.

11. The method according to claim 9 wherein the laser array is selected from the group consisting of diode laser and fiber laser.

12. A method of directly forming a silicon wafer sheet by:
i. providing a silicon feedstock rod with a rectangular cross section
ii. heating and refining the silicon feedstock rod to high purity using the float zone process
iii. attaching a seed crystal to the neck end of the silicon feedstock rod
iv. maintaining sufficient heat and pull speed at the neck to allow a silicon wafer to be drawn continuously.

13. The method according to claim 12 wherein the silicon feedstock rod has a rectangular cross section with an aspect ratio of at least 3, preferably between 20 and 40 and as high as 100.

14. The method according to claim 12 wherein the heating of the feedstock is accomplished by a combination of electromagnetic induction coil and laser array.

15. The method according to claim 12 wherein the silicon feedstock is refined to high purity suitable for solar cell fabrication.

16. The method according to claim 12 wherein float zone refining and wafer drawing is done in a single operation.

17. The method according to claim 12 wherein the silicon wafer is mono-crystalline.

18. The method according to claim 12 wherein the silicon wafer is multi-crystalline.
